(19) United States
(12) Patent Application Publication
(10) Pub. No.: US 2026/0010079 A1
(43) Pub. Date: Jan. 8, 2026

(54) APERTURE CORRECTION AMOUNT CALCULATION METHOD FOR APERTURE ARRAY SUBSTRATE, APERTURE ARRAY SUBSTRATE, BLANKING APERTURE ARRAY SUBSTRATE, MULTIPLE CHARGED-PARTICLE BEAM WRITING APPARATUS, AND MULTIPLE CHARGED-PARTICLE BEAM WRITING METHOD

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 19/252,632

(22) Filed: Jun. 27, 2025

(30) Foreign Application Priority Data
Jul. 3, 2024 (JP) 2024-107605

(51) Int. Cl. G03F 7/00; H01J 37/04; H01J 37/317; H01L 21/263

(52) U.S. Cl. CPC G03F 7/7025; G03F 7/70316; G03F 7/704; G03F 7/70508; G03F 7/70516; G03F 7/70525; H01J 37/045; H01J 37/3177; H01J 2237/0435; H01L 21/263

(57) ABSTRACT

In one embodiment, an aperture correction amount calculation method is for calculating a correction amount for positions or dimensions of a plurality of apertures formed in an aperture array substrate through which multiple charged particle beams pass. The method includes measuring a shift amount distribution on an irradiation surface, which is a distribution of shift amounts from a predetermined position or a predetermined current density of each beam within a beam array of the multiple charged particle beams, dividing the beam array into a predetermined number of block regions based on the shift amount distribution, and calculating a representative value of the shift amounts corresponding to each block region, and calculating, for each of the block regions, correction amounts for positions or dimensions of the corresponding apertures of the aperture array substrate based on the representative values.

### CROSS REFERENCE TO RELATED APPLICATION

This application is based upon and claims benefit of priority from the Japanese Patent Application No. 2024-107605, filed on Jul. 3, 2024, the entire contents of which are incorporated herein by reference.

### FIELD

The present invention relates to an aperture correction amount calculation method for aperture array substrate, an aperture array substrate, a blanking aperture array substrate, a multiple charged-particle beam writing apparatus, and a multiple charged-particle beam writing method.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed in a light-shielding film on quartz is transferred to a wafer in a reduced manner by using a reduced-projection exposure apparatus. The high-precision original pattern is written by using an electron-beam writing apparatus, in which a so-called electron-beam lithography technique is employed. In some cases, a so-called wafer direct writing method, in which a pattern is formed on a resist coated on the wafer by an electron beam, is used.

In a multibeam writing apparatus using a blanking aperture array substrate serving as a form of a multibeam writing apparatus, for example, an electron beam emitted from a single electron gun passes through a shaping aperture array substrate having multiple apertures to form multiple beams (multiple electron beams). The blanking aperture array substrate is located downstream of the shaping aperture array substrate. For each of the multiple beams, the blanking aperture array substrate has a pair of electrodes (a blanker) for deflecting the beam separately and a beam passage aperture formed between the pair of electrodes, and these are arranged in an array on the blanking aperture array substrate. The blanking aperture array substrate switches the blanking deflection of the passing beam off and on by controlling the pair of electrodes corresponding to each of the multiple beams to the same potential or controlling the pair of electrodes to different potentials from each other. The multiple beams formed by the shaping aperture array substrate pass through the passage apertures in the corresponding blankers of the blanking aperture array substrate. An optical column of the multibeam writing apparatus is configured to irradiate an exposure target substrate with undeflected electron beams along beam paths toward the substrate and shield electron beams deflected by the blankers and deviated from the beam paths.

In multibeam writing, the shift of each of the multiple beams from the ideal position and the deviation of the current density from the target value affect the accuracy of writing and throughput. The position of each of the multiple beams has a systematic shift distribution within the multibeam array due to distortion of the optical system, for example. The shifts of the beams cause an edge shift and undulation of the pattern to be exposed, and the position, dimensions, and edge roughness of the pattern are degraded. The current density of each of the multiple beams reflects the current density distribution of the beam with which the shaping aperture array substrate is irradiated, and has a systematic distribution within the multibeam array. A difference in the current density of each of the multiple beams can be corrected by modulating the beam irradiation time so that each beam delivers the correct irradiation dose to the writing target substrate regardless of the current density. However, this correction requires a long irradiation time for beams with low current density, resulting in a longer writing time due to the increased shot cycle for multibeam writing.

To mitigate these problems, a technique is known that estimates in advance a shift of each of the multiple beams and a deviation of current density of the beam and pre-defines distributions of the positions and sizes of the apertures of the shaping aperture array substrate to compensate for these shifts and deviations.

However, the error distribution of the irradiation position of each beam in the multiple beams and the current density of the beam will not be the same as the error distributions estimated in advance because the error distribution varies depending on the adjustment state of the multibeam writing apparatus and individual differences in components such as cathodes. In a case where the actual error distributions differ from the estimated distributions, the pre-defined distributions of the positions and sizes of the apertures of the shaping aperture array substrate may fail to reduce the actual errors and instead increase the errors in some cases. That is, the errors caused by the aperture correction of the shaping aperture array substrate can be larger than the actual (uncorrected) errors. Moreover, beam errors observed as the differences caused by the aperture correction based on the actual distributions and the estimated distributions may result in distributions that are more complex than the actual distributions.

In an electron beam writing apparatus, it is necessary to measure the position of a beam on the sample surface to adjust the optical system, which will be performed as follows. A mark for beam position detection is placed at the height where an exposure target substrate is placed, namely on the sample surface, and the beam is scanned over this mark to detect reflected electrons from the mark. By acquiring the amount of reflected electrons on a beam deflection amount basis, the change in the amount of reflected electrons due to beam scanning is acquired as a scan waveform, and the edge position of the mark is calculated by analyzing the scan waveform to obtain the position of the mark. In a multibeam writing apparatus, the accuracy of beam position measurement is low with a single beam scan because the amount of current of a single beam is small. Thus, high position measurement accuracy is obtained by scanning the mark with multiple beams grouped together to measure the average position of the grouped beams. In this case, preferably, the grouped beams have a uniform shift amount and the same current density for the analysis of the scan waveform. In a case where a shaping aperture array substrate with apertures corrected using an existing method is used, in a case where the estimated error distribution and the actual error distribution match, the grouped beams have a uniform shift amount and current density; however, in a case where the estimated error distribution and the actual error distribution do not match, the grouped beams may have a larger or more complex error distribution than the actual one.

Moreover, a technique is known that enables, in a case where the aperture positions of the shaping aperture array substrate are displaced, alignment of each of the multiple beams with the center of a corresponding one of the apertures of the blanking aperture array substrate by applying the same shift amounts as the positions of the apertures of the shaping aperture array substrate to the beam passage apertures of the blanking aperture array substrate. However, the blanking aperture array substrate includes wiring lines and control circuits for beam deflection, and thus the positions of the wiring lines and control circuits may need to be changed to displace the aperture positions of the blanking aperture array substrate. In a case where the aperture positions of the shaping aperture array substrate and blanking aperture array substrate are continuously displaced in accordance with the estimated beam error amounts, the positions of the wiring lines and control circuits of the blanking aperture array substrate need to be continuously displaced, and thus the difficulty of design modifications increases.

### BRIEF DESCRIPTION OF THE DRAWINGS

FIG. 1 is a schematic diagram of a multiple charged-particle beam writing apparatus according to an embodiment of the present invention.

FIG. 2 is a plan view of a shaping aperture array substrate.

FIG. 3 is a cross-sectional view of the configuration of a blanking aperture array substrate.

FIG. 4 is a schematic configuration diagram of a control circuit within the blanking aperture array substrate.

FIG. 5 is a configuration diagram of an input-output circuit and a cell array circuit.

FIG. 6 is a schematic configuration diagram of an individual blanking mechanism.

FIG. 7 is a flowchart illustrating a method for fabricating a shaping aperture array substrate with apertures whose positions and dimensions are corrected.

FIG. 8A is a diagram illustrating an example of a beam shift amount distribution, and FIGS. 8B and 8C are diagrams illustrating examples of block partitioning of shift amounts.

FIG. 9 is a diagram illustrating an example of mark scanning.

FIG. 10A is a diagram illustrating an example of a beam shift amount distribution, and FIGS. 10B and 10C are diagrams illustrating examples of block partitioning of shift amounts.

FIG. 11A is a diagram illustrating an example of a current density distribution, and FIG. 11B is a diagram illustrating an example of representative current density values of respective blocks.

FIG. 12 is a diagram illustrating an example of the position correction of individual blanking mechanisms.

### DETAILED DESCRIPTION

In one embodiment, an aperture correction amount calculation method is for calculating a correction amount for positions or dimensions of a plurality of apertures formed in an aperture array substrate through which multiple charged particle beams pass. The method includes measuring a shift amount distribution on an irradiation surface, which is a distribution of shift amounts from a predetermined position or a predetermined current density of each beam within a beam array of the multiple charged particle beams, dividing the beam array into a predetermined number of block regions based on the shift amount distribution, and calculating a representative value of the shift amounts corresponding to each block region, and calculating, for each of the block regions, correction amounts for positions or dimensions of the corresponding apertures of the aperture array substrate based on the representative values.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

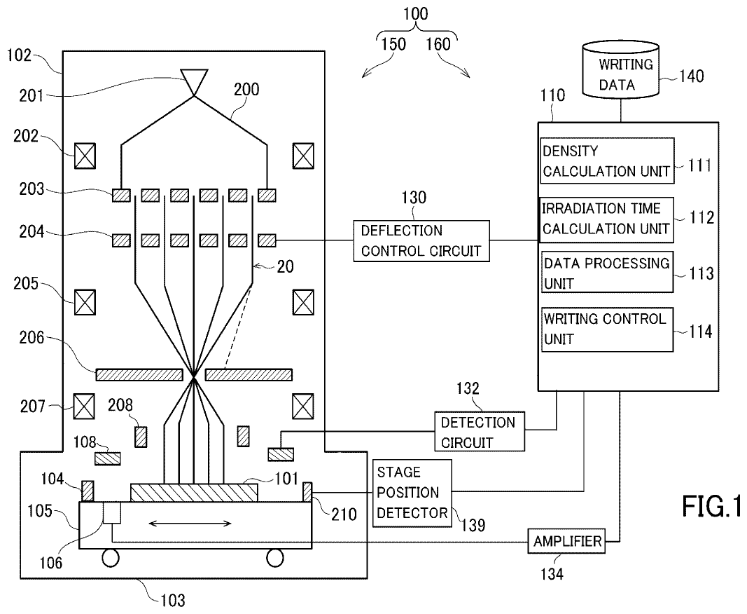

FIG. 1 is a schematic diagram of the configuration of a writing apparatus according to an embodiment. As illustrated in FIG. 1, a writing apparatus 100 includes a writing unit 150 and a control unit 160. The writing apparatus 100 is an example of a multiple charged-particle beam writing apparatus. The writing unit 150 includes an electron-optical column 102 and a writing chamber 103. In the electron-optical column 102, an electron gun 201, an illumination lens 202, a shaping aperture array substrate 203, a blanking aperture array substrate 204, a reduction lens 205, a limiting aperture member 206, an objective lens 207, and a deflector 208 are arranged.

In the writing chamber 103, an XY stage 105 and a detector 108 are arranged. On the XY stage 105, a substrate 101 used as a writing target is arranged. A resist to be exposed to an electron beam is applied to the top surface of the substrate 101. The substrate 101 is a mask blank that is processed into a photomask or a semiconductor substrate (silicon wafer) to be processed into semiconductor devices. A mark substrate 104, a Faraday cup 106, and a mirror 210 for stage position measurement are arranged on the XY stage 105. The output from the Faraday cup 106 is transmitted via an amplifier 134 to a control computer 110.

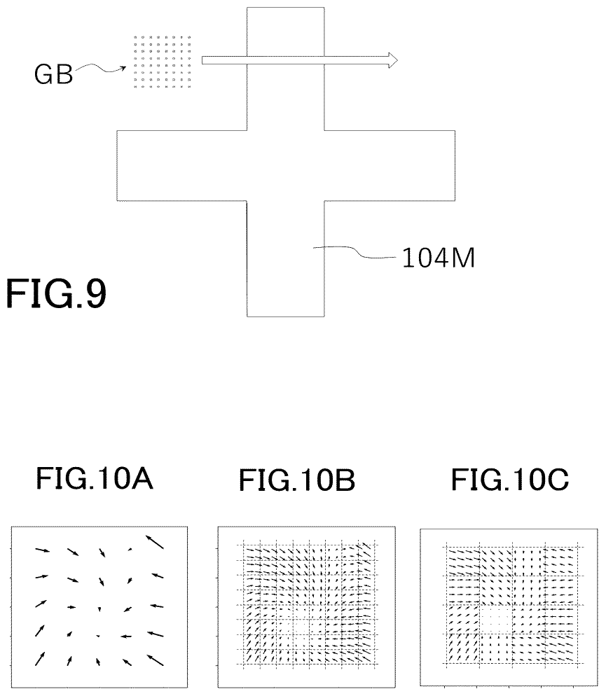

A mark 104M (see FIG. 9) for beam calibration is formed on the mark substrate 104. The mark 104M is formed of a material, such as metal, on a base made of silicon, for example, the material having higher electron reflectivity than the base. The mark 104M has a shape with edges in two orthogonal directions, for example, a cross shape. The mark 104M is scanned by an electron beam in the directions orthogonal to the edges to detect the beam position and an amount of blur. The detector 108 detects a reflected electron signal from the mark 104M when the electron beam scans the cross of the mark 104M.

The control unit 160 has the control computer 110, a deflection control circuit 130, a detection circuit 132, the amplifier 134, a stage position detector 139, and a memory unit 140. Writing data is input from the outside and stored in the memory unit 140. In the writing data, information regarding multiple graphic patterns to be written is defined. Specifically, for each graphic pattern, a graphic code, coordinates, size, and so forth are defined. Other information, such as dose control information, may additionally be defined in the writing data.

The control computer 110 has an area density calculation unit 111, an irradiation time calculation unit 112, a data processing unit 113, and a writing control unit 114. Each unit of the control computer 110 may be configured using hardware, such as electrical circuits, or software, such as a program that executes these functions. Alternatively, each unit of the control computer 110 may be configured using a combination of hardware and software.

The stage position detector 139 emits a laser to the mirror 210, receives reflected light from the mirror 210, and detects the position of the XY stage 105 using laser interferometry.

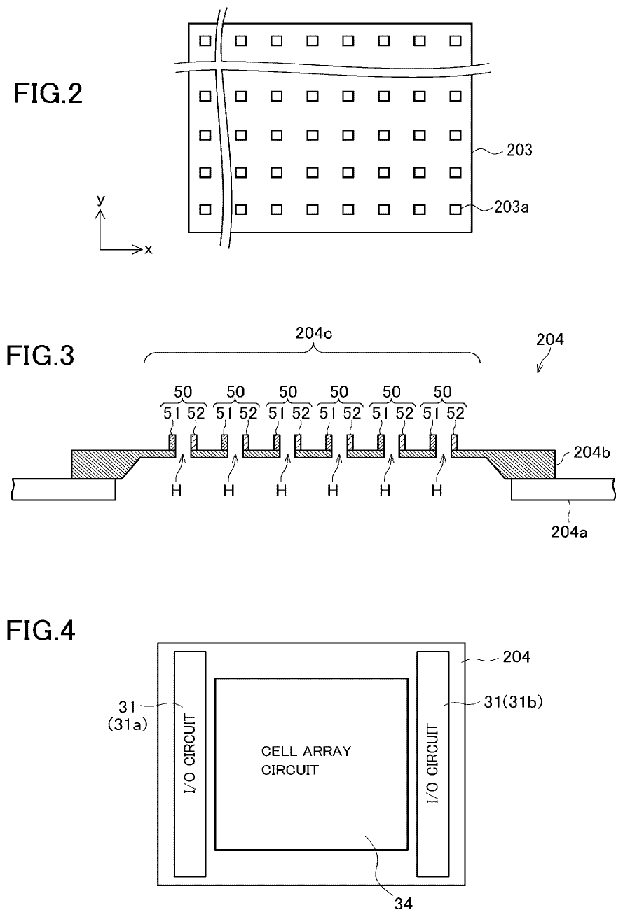

FIG. 2 is a conceptual diagram illustrating the configuration of the shaping aperture array substrate 203. The shaping aperture array substrate 203 is a plate-shaped member. As illustrated in FIG. 2, in the plane of the shaping aperture array substrate 203, multiple apertures 203a are formed along the vertical direction (y-direction) and the horizontal direction (x-direction). Each aperture 203a is formed in a rectangular shape or a circular shape.

An electron beam 200 emitted from the electron gun 201 (a beam source) is caused to illuminate the shaping aperture array substrate 203 by the illumination lens 202. The electron beam 200 illuminates a region of the shaping aperture array substrate 203 that includes all of the apertures 203a. Portions of the electron beam 200 pass through multiple apertures 203a of the shaping aperture array substrate 203 and the rest of the beam is stopped by the shaping aperture array substrate 203, so that multiple electron beams, namely multiple beams 20, are formed. The shapes of respective beams (individual beams) of the multiple beams 20 follow the shapes of the apertures 203a of the shaping aperture array substrate 203 and are, for example, rectangular.

As illustrated in FIG. 3, the blanking aperture array substrate 204 has a support base 204a and a semiconductor substrate 204b, which is made of silicon, for example, and provided on the support base 204a. The central portion of the semiconductor substrate 204b is thinly shaved from the back side and processed into a membrane region 204c having a thin film thickness. The region surrounding the membrane region 204c is a peripheral region having a large film thickness, and the semiconductor substrate 204b is held on the support base 204a at the backside of the peripheral region. The central portion of the support base 204a is open, and the membrane region 204c is located in the open region of the support base 204a.

The membrane region 204c has multiple beam passage apertures H formed so as to be aligned with the arrangement positions of the respective apertures 203a of the shaping aperture array substrate 203. A blanker 50 formed by a set of two electrodes 51 and 52, serving as a pair, is arranged in each passage aperture H, and one of the multiple beams passes between the pair of electrodes and through the passage aperture H. By keeping the electrode 52 grounded to have ground potential and switching the other electrode 51 between the ground potential and a potential other than the ground potential, the blanker 50 switches the deflection of the beam passing through the passage aperture H between off and on. This allows the blanker 50 to perform blanking control in which each of the multiple beams is set to either a beam-on state or a beam-off state. The principle of blanking control is described below.

In a case where one individual beam among the multiple beams is controlled to be in the beam-on state, the opposing electrodes 51 and 52 of the blanker 50 are controlled to maintain the same potential, and the blanker 50 does not deflect the beam passing through the passage aperture H. In a case where the one individual beam is controlled to be in the beam-off state, the opposing electrodes 51 and 52 of the blanker 50 are controlled to maintain different potentials from each other, and the blanker 50 deflects the beam passing through the passage aperture H.

The multiple beams 20 that have passed through the blanking aperture array substrate 204 are reduced by the reduction lens 205 and proceed toward the central aperture formed in the limiting aperture member 206.

In this case, the beams that are controlled to be in the beam-off state are deflected by the blankers 50 and are shielded by the limiting aperture member 206 because the beams travel along trajectories that pass outside the aperture of the limiting aperture member 206. In contrast, the beams that are controlled to be in the beam-on state are not deflected by the blankers 50 and pass through the aperture of the limiting aperture member 206. The beam trajectories are adjusted using an alignment coil (not illustrated) so that the beams controlled to be in the beam-on state are located within the aperture of the limiting aperture member 206. In FIG. 1, the multibeam trajectories are adjusted so that the multiple beams in the beam-on state are focused on a single point at the location of the limiting aperture member 206, but it is preferable that the alignment coil be adjusted so that this single point is at the central portion of the aperture of the limiting aperture member 206. In this manner, for each of the multiple beams, the on-off state of the beam is controlled by the combination of the on-off operation of the deflection of the blanker 50 and the shielding of the beam by the limiting aperture. That is, blanking control is performed.

The multiple beams 20 that have passed through the limiting aperture member 206 are focused by the objective lens 207 to form a pattern image with a desired reduction ratio on the substrate 101. The multiple beams are ideally aligned on the substrate 101 at a pitch obtained by multiplying the array pitch of the multiple apertures 203a of the shaping aperture array substrate 203 by the desired reduction ratio described above. The individual beams (all beams that are in the beam-on state among the multiple beams) that have passed through the limiting aperture member 206 are deflected in a collective manner in the same direction by the deflector 208. The desired position on the substrate 101 is irradiated with the deflected beams focused on the surface of the substrate 101.

It is possible to irradiate the substrate 101 with the multiple beams even in a state where the XY stage 105 is stationary or in a state where the XY stage 105 is moving continuously. In a case where the XY stage 105 is moving continuously, the stage position detector 139 measures the amount of change in the stage position, and the result is used to continuously change, using the deflector 208, the positions of the multiple beams to follow the movement of the XY stage 105. This is called stage tracking deflection. The stage tracking deflection allows the positions of the multiple beams to be fixed on the substrate 101. At least while the substrate 101 is being irradiated with the beams, the stage tracking deflection is performed to control the position of each of the multiple beams on the substrate 101 to be fixed.

The blanking aperture array substrate 204 has a control circuit for applying a desired voltage to the blankers 50, in addition to the above-mentioned blankers 50 and the passage apertures H. As illustrated in FIG. 4, this control circuit has an input-output circuit 31 and a cell array circuit 34.

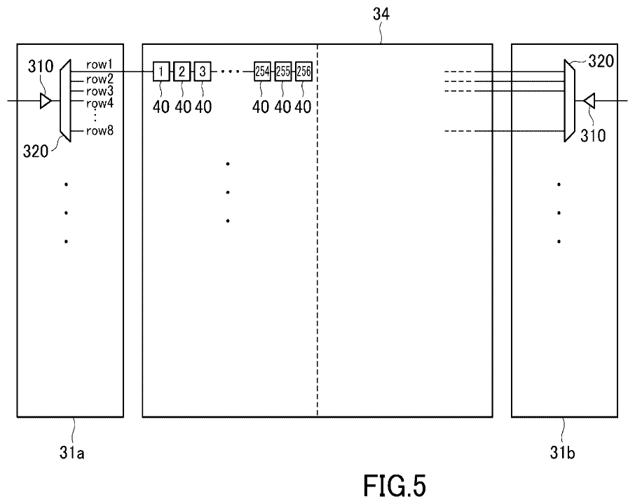

As illustrated in FIG. 5, the cell array circuit 34 has multiple cells that constitute individual blanking mechanisms 40 for driving the blankers 50. FIG. 5 illustrates an example of a blanking aperture array substrate with 262,144 cells and blankers consisting of 512 rows and 512 columns. One individual blanking mechanism 40 drives one blanker 50. The input-output circuit 31 outputs, to the cell array circuit 34, the data received from the deflection control circuit 130. For example, the input-output circuit 31 has an input-output circuit 31a and an input-output circuit 31b. The input-output circuit 31a outputs data to the individual blanking mechanisms 40 arranged on one half of the cell array circuit 34. The input-output circuit 31b outputs data to the individual blanking mechanisms 40 arranged on the other half.

The input-output circuit 31 includes multiple selectors 320 (demultiplexers). Each selector 320 receives, via an amplifier 310, blanking control data that defines the on-off state of each beam and outputs the blanking control data from the corresponding output lines. To each output line, multiple individual blanking mechanisms 40 are connected in series.

The selector 320 has, for example, eight output lines row1 to row8, and 256 individual blanking mechanisms 40 are connected to each output line. By arranging 64 selectors 320 in each of the input-output circuits 31a and 31b, the blanking control data can be transferred to 512×512 individual blanking mechanisms 40 constituting the cell array circuit 34.

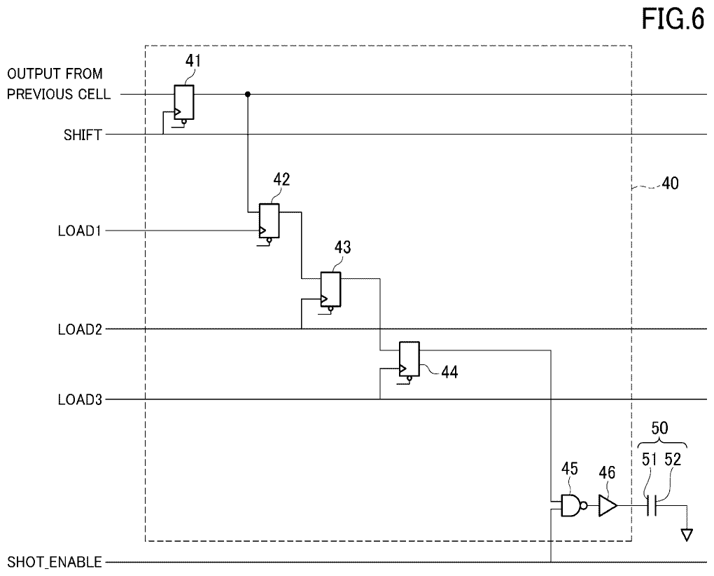

As illustrated in FIG. 6, each individual blanking mechanism 40 has a shift register 41, a pre-buffer 42, a buffer 43, a data register 44, a NAND circuit 45, and an amplifier 46. The shift register 41 transfers, in accordance with a clock signal (SHIFT), data output from the shift register of the previous cell to the shift register of the subsequent cell.

The pre-buffer 42 stores, in accordance with a clock signal (LOAD1), the blanking control data for that cell output from the shift register 41.

The buffer 43 receives and holds the output value from the pre-buffer 42 in accordance with a clock signal (LOAD2).

The data register 44 receives and holds the output value from the buffer 43 in accordance with a clock signal (LOAD3).

To the NAND circuit 45, the output signal from the data register 44 and a shot enable signal (SHOT_ENABLE) are input. The output signal from the NAND circuit 45 is supplied to the electrode 51 of the blanker 50 via the amplifier 46 (a driver amplifier).

In a case where both the output signal from the data register 44 and the shot enable signal are High, the output from the NAND circuit 45 is Low, and this makes the electrodes 51 and 52 have the same potential. The beam is thus turned on because the blanker 50 does not deflect the beam. In a case where at least one of the output signal from the data register 44 and the shot enable signal is Low, the output from the NAND circuit 45 is High, and this makes the electrodes 51 and 52 have different potentials. The beam is thus turned off because the blanker 50 deflects the beam.

The shot enable signal is input to the NAND circuits 45 of all the individual blanking mechanisms 40. By setting the shot enable signal to Low, all the beams can be turned off regardless of the output signal from the data register 44.

In a state where the shot enable signal is kept High, the beam is switched between on and off in accordance with the output from the data register 44. That is, the beam is on in a case where the blanking control data is 1 (High) and off in a case where the blanking control data is 0 (Low). After transferring the blanking control data to the individual blanking mechanism 40, by setting the shot enable signal to High only for the duration of an irradiation time, the desired beam can be turned on and the sample can be irradiated with the beam during a predetermined irradiation time. This blanking control can be combined with beam position control performed by the deflector 208 to perform writing using multiple beams.

In the multiple-beam writing apparatus, the electron-optical system is adjusted before writing. In this adjustment process, a method is used in which the position and resolution of multiple beams are measured by scanning the multiple beams over the mark 104M. In the case of a writing apparatus with a large number of multiple beams, the mark 104M is scanned by a subset of beams grouped together among the multiple beams. This method allows, for example, the adjustment of the focus position of the multiple beams (for example, see Japanese Unexamined Patent Application Publication No. 2018-67605).

In the present embodiment, the shaping aperture array substrate 203 is used, which is fabricated by shifting the positions and dimensions of the apertures 203a such that the current density distribution of the beam array and the error distribution of beam positions on the sample surface are reduced, the distributions being estimated in advance. In this case, the positions and dimensions of the apertures 203a are corrected in units of blocks, which are in a predetermined arrangement. That is, the amount of correction is determined for each block, and the same amount of correction is applied to the apertures within the block. This arrangement of the blocks is set such that a beam group scanning the mark 104M for beam adjustment is included (fits in).

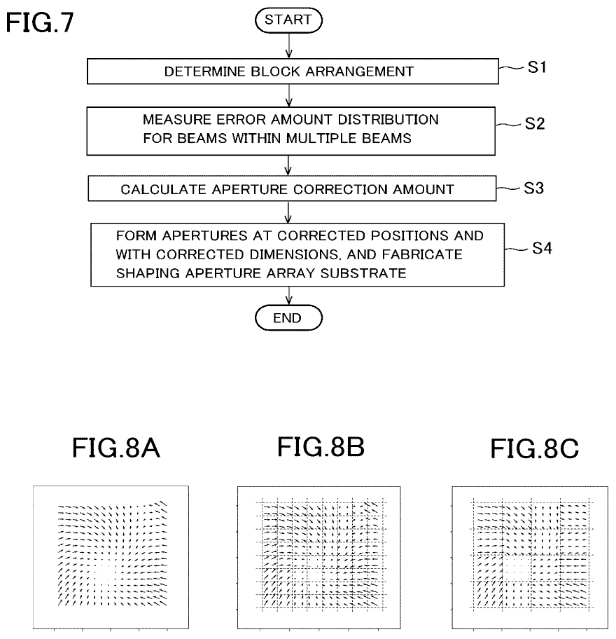

FIG. 7 is a flowchart illustrating a method for fabricating a shaping aperture array substrate with apertures whose positions and dimensions are corrected. Apertures of the same size are equally spaced on the shaping aperture array substrate before the positions and dimensions of the apertures are corrected.

In a block arrangement determination process (S1), the arrangement of blocks for correcting the positions and dimensions of the apertures of the shaping aperture array substrate is determined. For example, the beam array of multiple beams is divided into regions, such as 7×7, 8×8, or 9×9 regions, and the division regions are treated as blocks. A rectangular shape is suitable for the blocks. When the number of blocks is determined, the arrangement of the blocks is also determined. Additionally, the size of each block does not need to be the same. For example, in a case where the number of beams of the beam array in the x-direction is not divisible by the number of blocks in the x-direction, the size of at least one block in the x-direction will be different from the size of the other blocks. The arrangement of the blocks is determined so that each block includes a partial array used for mark scanning.

For example, in a case where 32×32 beams are used for mark scanning, the multiple beams constituted by 512×512 beams are divided into 8×8 blocks. In this case, each block includes 64×64 beams, and thus 32×32 beams used for scanning, namely a partial array, are included in a single block.

In an error amount distribution measurement process for the beams within the multiple beams (S2), either one of or both the current density distribution and the distribution of shift amounts in the irradiation position of each of the multiple beams are measured as error amount distributions. In a case where the positions of the apertures of the shaping aperture array substrate are to be corrected, the distribution of shift amounts is measured. In a case where the dimensions of the apertures of the shaping aperture array substrate are to be corrected, the current density distribution is measured. In a case where both the positions and dimensions of the apertures of the shaping aperture array substrate are to be corrected, both the distribution of shift amounts and the current density distribution are measured. Preferably, the measurement is performed using an apparatus in which a corrected shaping aperture array substrate is mounted, or multiple apparatuses having the same configuration as the apparatus in which the corrected shaping aperture array substrate is mounted, and the amounts of correction are determined from the average values of the measurement results of the apparatuses. In the error amount distribution measurement process (S2), the shaping aperture array substrate before the aperture correction is mounted in the writing apparatus. Alternatively, in a case where the shaping aperture array substrate after the aperture correction is mounted, the amounts of correction applied to the apertures are subtracted to calculate the distribution of shift amounts and an amount-of-current distribution.

One method for measuring the distribution of shift amounts in the irradiation position of each of the multiple beams is a method for performing writing using multiple beams. An evaluation substrate (mask blank) coated with a resist is irradiated with multiple beams to write a pattern for beam irradiation position evaluation, and the position of the written pattern formed by developing or further etching the evaluation substrate is measured by a position measurement device. Writing is performed using a step-and-repeat method. In writing performed using the step-and-repeat method using multiple beams, in a state where the position of the stage on which the evaluation substrate is mounted is fixed, a region of the same size as the beam array on the evaluation substrate is exposed to multiple beams as the multiple beams scan the evaluation substrate using deflection less than or equal to the beam pitch. In this method of writing, since the alignment of the beams within the beam array matches the alignment of the positions on the evaluation substrate surface exposed to each beam, the shift distribution of the beams within the beam array is transferred as the shift distribution of the writing pattern. Thus, by measuring the shift of the writing pattern using the position measurement device, the distribution of relative shifts of the beams within the beam array at the time of writing can be obtained.

In a case where the position of the writing pattern is measured using the position measurement device, it is preferable that the size of the pattern be somewhat larger to obtain higher measurement accuracy. Preferably, the size of the pattern is larger than the beam pitch. In this case, a single pattern is exposed to multiple beams, and the average position of multiple beams that write the outer periphery of the pattern is measured as the shift of the writing pattern. By arranging such a pattern in a grid manner in the regions of the same size as the beam array and performing writing in a step-and-repeat method, the distribution of relative shifts of the beams within the beam array can be obtained from the position measurement results of the pattern formed through writing.

FIG. 8A illustrates an example of the distribution of shift amounts obtained from the writing results of the evaluation substrate.

As another method of measuring the distribution of shift amounts of beams within the multiple beams, the mark position may be measured by scanning the mark 104M using multiple beams, and beam shift amounts may be calculated from the measured apparent shift amounts of the mark position. Specific examples are described below. First, multiple measurement points for shift amounts within the multiple beams are determined. This arrangement does not have to correspond to the arrangement of the blocks in the block determination process (S1). For example, 5×5 points within the multiple beams are arranged. For each measurement point, multiple beams included in the region that includes the measurement position are grouped together, and the grouped beams are set as a partial array (an on-beam region).

Next, the position of the XY stage 105 on which the mark 104M is mounted is moved such that the mark 104M is positioned at a design irradiation point of the partial array (on-beam region) corresponding to one of the measurement points. The position of the XY stage 105 in this case is detected by the stage position detector 139 and thus the position of the mark 104M can be accurately controlled. Next, as illustrated in FIG. 9, in a state where only the partial array (on-beam region) of the multiple beams is turned on, while causing this to scan across the edge portion of the mark 104M using the deflector 208, electrons reflected by the mark 104M are detected by the detector 108. For each deflection amount during the scan, the detection circuit 132 transmits the amount of electrons reflected from the mark 104M and detected by the detector 108 to the control computer 110. For each deflection amount during the scan, the control computer 110 obtains the deflection amount and the detected amount of reflected electrons as a scan waveform, and then calculates the edge positions of the mark 104M from the scan waveform to calculate the position of the mark 104M in the deflection coordinate system. In a case where the beams of the partial array that scans the mark 104M have a shift from the ideal positions, the position of the mark detected in this manner is detected so as to have a shift that has the opposite sign to the shift amount of the beams. For example, in a case where the beams of the partial array are displaced by 5 nm in the x-direction, the mark 104M is observed to have a shift of −5 nm in the x-direction in the mark scan. By considering this point, as a shift as large as the apparent shift amount of the mark position observed in mark scanning and having the opposite sign, the shift amount of the beams of the partial array is obtained.

Next, using the partial array at another measurement point, the position of the partial array is similarly calculated. By repeating this, the position of the partial array (on-bean region) at each measurement point within the beam array can be obtained. By subtracting the average value of the position of each partial array from the position of the partial array, the distribution of relative shift amounts of the beams at the respective measurement points within the beam array is calculated.

FIG. 10A illustrates an example in which, for 5×5 points within the multiple beams, a beam position measurement is performed through mark scanning for the partial array (on-beam region) at each position, and the distribution of beam shifts within the multiple beams is calculated. Next, in the error amount distribution measurement process (S2) for the beams in the multiple beams, a method for measuring the current density distribution within the beam array will be described. First, multiple measurement points for the current density distribution within the beam array are determined. This arrangement does not have to correspond to the arrangement of the blocks in the block determination process (S1). For example, 5×5 points or 16×16 points within the beam array are arranged. For each measurement point, a partial array (an on-beam region) of the multiple beam is set in a region that includes the measurement point. Only the partial array of the multiple beams to be measured is turned on, and the amount of current of beams of the partial array reaching the Faraday cup 106 is measured. Then, the design beam size on the sample surface or the beam size on the sample surface calculated from the pre-measured aperture dimensions of the shaping apertures and the reduction ratio of the optical system, and the number of beams belonging to the partial array are used to convert the amount of current of the partial array into the average current density of the beams in the partial array. The current density distribution within the beam array is calculated by switching the partial array to be turned on (on-beam region) and measuring the amount-of-current distributions at all measurement points. In this manner, the current density distribution cannot be measured directly, but is based on amounts estimated from the amounts of current of the beams and the dimensions of the apertures. Therefore, the current density distribution described below is the effective current density distribution including the effect of any deviation of the aperture dimensions of the shaping apertures from the design value if there is such a deviation.

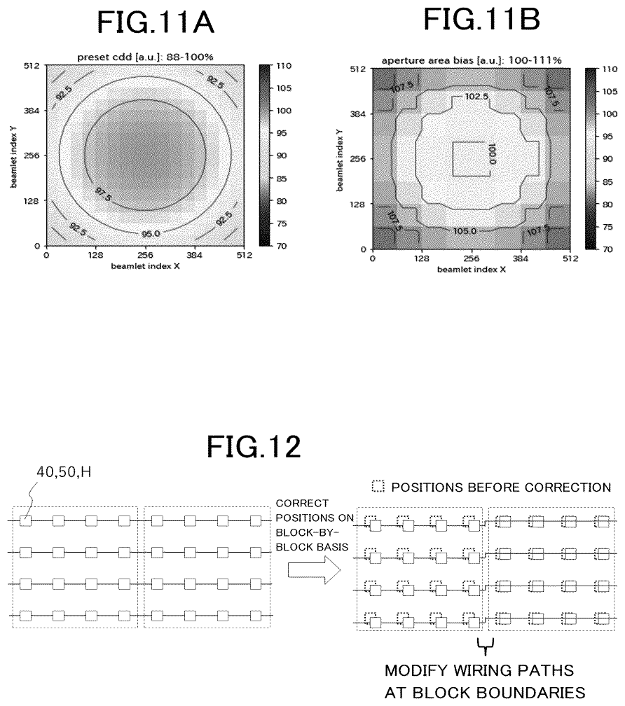

The current density measurement of each partial array can be completed in a shorter time than the beam position measurement through mark scanning of the partial array. Thus, more measurement points can be used than for the beam position measurement. In a case where the multiple beams are 512×512 beams, the current density distribution measurement can be performed, for example, with 16×16 measurement positions and a partial array size of 32×32, which is allocated to each measurement position. In this case, the partial arrays are adjacent to each other without gaps. This measurement results in a current density distribution in the form of a color map in FIG. 11A, for example.

In an aperture correction amount calculation process (S3 in FIG. 7), an aperture position correction amount is calculated using the shift amount distribution obtained in the error amount distribution measurement process (S2), and the correction amount for the aperture dimensions is calculated using the current density distribution. In either case, from the error amount distribution obtained in the error amount distribution measurement process (S2), a representative error amount value is determined for each block determined in S1, and this is set as the aperture correction amount for the block.

An example of the calculation of the aperture position correction amount will be described. First, an example of a case is described in which the number of error amount measurement points is greater than the number of blocks, that is, there are multiple measurement points per block. In a case where the shift distribution is measured for many measurement points as in FIG. 8A, each block determined in S1 includes multiple measurement points. In this case, preferably, the average value of the error amounts of the measurement points included in each block is obtained and this is used as the correction amount for that block. FIG. 8B illustrates an example of a case where 8×8 blocks are determined in S1. FIG. 8C illustrates an example of a case where 4×4 blocks are determined in S1. In FIGS. 8B and 8C, representative values of the respective blocks are displayed at the measurement points. Although there are multiple apertures in each block, it is clear from FIGS. 8B and 8C that the correction amounts for the aperture positions are uniform within each block and discontinuous between blocks. The correction amount for each block in FIGS. 8A to 8C may be not the average value but the median value of the errors for the measurement points included in the block.

An aperture position correction amount Δs is expressed by the following equations. In the following equations, i and j are indices that identify the blocks within the beam array. X represents the measured shift amount. xₖ is the coordinates of a measurement point belonging to the block (i, j).

$$\begin{matrix}Representative value is average value : Δ s ( i , j ) = \overline{X ( {x}_{k} )} \\ Representative value is median value : Δ s ( i , j ) =\end{matrix} \} \qquad Equation 1$$

Next, an example of a case will be described in which the number of measurement points is smaller than or comparable to the number of blocks. The number of measurement points for the shift amount measured through mark scanning is less than that for the shift amount obtained from the writing results on the evaluation substrate due to the limitation of measurement time. Thus, the number of measurement points is often smaller than or compatible to the number of blocks. In this case, polynomial fitting such as X(xₖ)=fₓₘ(xₖ) is performed using the shift amount Xₘ(xᵢ) measured through mark scanning, shift amounts for evaluation points, which are greater in number than the number of measurement results, are estimated using the polynomial with coefficients determined by the fitting, and the representative value of each block is determined from one or preferably multiple evaluation points belonging to the block.

Specific examples are described below. In a case where the shift distribution is measured for 5×5 measurement points as in FIG. 10A, this shift amount distribution is fitted with a polynomial, for example, a cubic polynomial. Furthermore, from the fitting results, 16×16 evaluation points, which are greater in number than the number of blocks, are set and the shift amount at each evaluation point is calculated. Next, the average value of the shift amounts of the evaluation points included in each block is obtained and this is used as the representative value of that block. FIG. 10B illustrates an example of a case where 8×8 blocks are determined in S1. FIG. 10C illustrates an example of a case where 4×4 blocks are determined in S1. In FIGS. 10B and 10C, the representative value of each block is displayed at each evaluation point.

In this manner, using a function f obtained by polynomial fitting the error amount X(xₖ) obtained from the measurement, error amounts X(x′ₖ) at evaluation points x′ₖ, which are greater in number than the number of measurement points, can be estimated to calculate a correction amount for each block.

$$\begin{matrix}Representative value is average value : Δ s ( i , j ) = \overline{X ( {x}_{k}^{′} )} \\ Representative value is median value : Δ s ( i , j ) = \\ X ( {x}_{k}^{′} ) = f ( {x}_{k}^{′} )\end{matrix} \} \qquad Equation 2$$

Furthermore, a method for calculating an aperture dimension correction amount will be described. In FIG. 11A, there are measurement data for 16×16 points, which are greater in number than the number of blocks. Thus, in a case where the number of blocks is 8×8 or 4×4, it is possible to determine the current density for each block by taking the average value of the measurement data included in each block, similarly to as in Equation 1 described above. Note that, empirically, the current density distribution is often expressed as a quadratic polynomial. A quadratic function is set as a distribution that is expected to have a certain level of reproducibility between different solids such as the writing device and a cathode. By fitting the measurement data using this function and setting the same or different evaluation points as the measurement points and obtaining the amounts of error at the evaluation points from the fitting results, the amounts of correction expected to have a preferable reproducibility can be obtained. FIG. 11B illustrates the results of calculating, for each of 8×8 blocks, the representative values of the current densities at 16×16 evaluation points, the current densities being obtained from the fitting results. This method is similar to Equation 2 described above in that the representative values of the respective blocks are calculated from the fitting results. Alternatively, the average value of the current densities at the measurement points belonging to the block can be used as the representative value of the block, similarly to as in Equation 1, without using fitting. Moreover, for each block, the median value as well as the average value of the current densities can be used as the representative current density value of the block. Note that, instead of a current density distribution J(xₖ), a normalized current density distribution J(xₖ)/J₀ and the representative values of the respective blocks may be obtained, where J₀ is a design value of current density.

Next, as described in the following equations, using the representative value of current density for each block is used to obtain an aperture area correction amount Δa, and the aperture area correction amount Δa is used to calculate a dimension correction amount Δw. In the following equations, i and j are indices that identify the blocks. xₖ indicates the coordinates of a measurement point or evaluation point belonging to the block (i, j). a₀ denotes the design aperture size, J₀ denotes the design current density, and J(xₖ) denotes the measured current density. The calculated aperture area correction amount ratio Δa(i, j)/a₀ is illustrated in FIG. 11B. There are multiple apertures in each block, and thus it is clear from FIG. 11B that the correction amount for the aperture dimensions is uniform within each block and discontinuous between blocks.

$$\begin{matrix}Representative value is average value : Δ a ( i , j ) = {a}_{0} \times {J}_{0} / \overline{J ( {x}_{k} )} \\ Representative value is median value : Δ a ( i , j ) = {a}_{0} \times {J}_{0} / \\ Δ w ( i , j ) = \sqrt{Δ a ( i , j ) + {a}_{0}} - {a}_{0}\end{matrix}$$

As described above, the aperture correction amount (the position correction amount and the dimension correction amount) can be obtained from the measurement results for a single writing apparatus. From these results, it is possible to fabricate shaping aperture array substrates with apertures whose positions and dimensions are corrected. However, the beam shift distribution and current density distribution will vary to some extent from apparatus to apparatus or from adjustment to adjustment due to variations in the adjustment of the electron-optical system and in the fabrication of the electron-optical column and cathode. Therefore, it is desirable to perform aperture correction using the average values of the beam shift and current density distributions measured using multiple writing apparatuses and cathodes as the distributions with expected reproducibility. That is, it is desirable to perform aperture correction using multiple measurement results acquired by replacing the cathode or adjusting the beam multiple times with an apparatus having the same configuration as the apparatus in which the shaping aperture array substrate with corrected apertures is mounted, or the average value of multiple measurement results acquired by multiple apparatuses of the same configuration.

Using the aperture correction amounts (the position correction amounts and the dimension correction amounts) calculated for each block using such a method, the apertures 203a are formed at the corrected positions and with corrected dimensions on a block-by-block basis to fabricate the shaping aperture array substrate 203 (S4 in FIG. 7). In the fabricated shaping aperture array substrate 203, the aperture array is divided into blocks, and the positions of the apertures 203a are shifted on a block-by-block basis. Within the same block, the apertures 203a are equally spaced, and the spacing between the apertures 203a at the block boundaries takes different values. In addition, the dimensions of the apertures 203a are different on a block-by-block basis.

The fabricated shaping aperture array substrate 203 is mounted on the writing apparatus 100 illustrated in FIG. 1, and after adjusting the electron-optical system, the substrate 101 is irradiated with multiple beams to write a pattern.

In a case where the multibeam shift distribution and current density distribution match or do not deviate significantly from the distributions estimated in advance, the positions and dimensions of the apertures 203a of the shaping aperture array substrate 203 are corrected. Thus, the positional accuracy of multiple beams with which the substrate 101 is irradiated is higher than a case where an uncorrected shaping aperture array substrate is used, and the pattern is expected to be written with high accuracy. In addition, the uniformity in the amount of current for each of the multiple beams is higher than a case where an uncorrected shaping aperture array substrate is used. Thus, an irradiation time correction amount for the current density distribution correction, namely to achieve a uniform irradiation dose per multibeam irradiation, is smaller, and thus the shot cycle increase is expected to be suppressed, leading to improved writing throughput.

During the adjustment phase of the electron-optical system before writing, the mark 104M is scanned by partial beam arrays. The positions or dimensions of the apertures 203a of the shaping aperture array substrate 203 are corrected on a block-by-block basis, where each block includes a partial array, and thus the correction amount for the beams belonging to the partial beam array is uniform. Thus, the same method as the existing method used for shaping aperture array substrates without aperture correction can be used in processing mark-scan waveforms. Even in a case where the expected error amount distribution is different from the actual error amount distribution during or after the adjustment of the optical system, the error amount distribution within the partial array will not be worse than the actual error amount distribution. Thus, the error amount distribution, which affects writing accuracy, can be corrected on a block-by-block basis while maintaining the reliability of mark scanning. The aperture correction is performed based on the state in which the beam adjustment is completed and the multibeam shift distribution and current density distribution are minimized; however, the distributions will have larger shifts than or be different from those in this state before or during the beam adjustment. In particular, in the adjustment of the optical system, in order to find optimal excitation values for the lenses and the alignment coils, the multibeam shift distribution and current density distribution are measured in a state shifted from the optimal values. Thus, even in such a state, namely a state with distributions having larger shift amounts than or being different from those with which the aperture correction amounts were determined, it is important that the correction of apertures does not adversely affect mark scanning.

Next, the correction of the aperture positions of the blanking aperture array substrate will be described. The blanking aperture array substrate 204 has the passage apertures H (second apertures) formed so as to be aligned with the arrangement positions of the apertures 203a of the shaping aperture array substrate 203. Thus, when the positions of the individual blanking mechanisms 40 including the passage apertures H and the blankers 50 are corrected on the basis of the position correction of the apertures 203a of the shaping aperture array substrate 203, it facilitates the alignment of multiple beams with the aperture array of the blanking aperture array in a case where a shaping aperture array substrate with apertures whose positions are corrected is used. In the present embodiment, as described above, the positions of the apertures 203a of the shaping aperture array substrate 203 are corrected on a block-by-block basis, and thus the positions of the individual blanking mechanisms 40 are also divided into blocks, the number of which is the same as the number of blocks for the apertures 203a, and corrected on a block-by-block basis. In a case where the positions of the individual blanking mechanisms 40 are to be corrected, as described below, it is preferable that the number of blocks determined in S1 of FIG. 7 be set to an even-by-even configuration, such as 8×8, and the LSI circuit of the blanking aperture array substrate 204 can be designed on a block-by-block basis, where the blocks have the same size as the blocks determined in S1 of FIG. 7.

For example, as illustrated in FIG. 12, the positions of the individual blanking mechanisms 40 are corrected on a block-by-block basis, and the blanking aperture array substrate 204 is fabricated. The blanking aperture array substrate 204 is fabricated by creating an LSI chip or wafer with control circuits and MEMS processing this to form a structure including the blankers and passage apertures H. That is, the design and creation of a blanking aperture array substrate requires two components: the LSI wafer or chip and the MEMS wafer or chip. By setting the position correction of the individual blanking mechanisms 40 on a block-by-block basis, design changes in LSI circuits can be handled by shifting circuits and wiring lines for each block and modifying wiring paths at the block boundaries. That is, since design changes other than shifting are limited to modifying the wiring paths at the block boundaries, the amount of design changes in the LSI circuits is reduced compared to the case where the position of each of the individual blanking mechanisms 40 is corrected independently. Thus, it facilitates design and fabrication of LSI circuits for blanking aperture arrays with apertures whose positions are shifted. Similarly, since design changes in the MEMS structure can be handled by shifting the MEMS structure on a block-by-block basis and changing the design of the MEMS structure at the block boundaries, it facilitates design and fabrication of MEMS structures with apertures whose positions are corrected.

The blanking aperture array is a complex chip with hundreds of thousands of individual blanking mechanisms and control circuits, but depending on whether or not the operation failure of an LSI circuit or the formation failure of the MEMS structure occurs at a block boundary, it is possible to distinguish whether the failure is caused by a design change to shift the positions of the apertures or by other factors, such as the LSI fabrication process or the MEMS process. This facilitates the fabrication and quality control of blanking aperture arrays with apertures whose positions are shifted.

In the above-described embodiment, an example of correcting the positions and dimensions of the apertures 203a of the shaping aperture array substrate 203 has been described; however, the apertures 203a of the shaping aperture array substrate 203 may be corrected in either position or dimension only. In addition, the apertures of the blanking aperture array substrate 204 may be corrected not only in position but also in dimension, or the apertures of the blanking aperture array substrate 204 may be corrected in dimension only.

According to the above-described embodiment, even in a case where the aperture correction amount distribution and the actual beam error amounts, namely the shift and current density distributions, do not match, the aperture correction prevents the error distributions within the subsets of the multiple beams from being worse than they actually are, thereby preventing the aperture correction from adversely affecting the mark scanning process even in such a case. It is also possible to facilitate design changes in the wiring lines and control circuits within the blanking aperture substrate in a case where the aperture positions of the blanking aperture array substrate are corrected.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An aperture correction amount calculation method for an aperture array substrate, the aperture array substrate including a plurality of apertures through which multiple charged particle beams pass, the aperture correction amount calculation method being a method for calculating a correction amount for positions or dimensions of the plurality of apertures, the method comprising:
measuring a shift amount distribution on an irradiation surface, which is a distribution of shift amounts from a predetermined position or a predetermined current density of each beam within a beam array of the multiple charged particle beams;
dividing the beam array into a predetermined number of block regions based on the shift amount distribution, and calculating a representative value of the shift amounts corresponding to each block region; and
calculating, for each of the block regions, correction amounts for positions or dimensions of the corresponding apertures of the aperture array substrate based on the representative values.

2. The aperture correction amount calculation method for an aperture array substrate according to claim 1, wherein an evaluation substrate is irradiated with the multiple charged-particle beams to write an evaluation pattern, a position where the evaluation pattern is written, is measured, and the shift amount distribution is obtained using a measurement result of the position of the evaluation pattern.

3. The aperture correction amount calculation method for an aperture array substrate according to claim 1, wherein a mark is irradiated with beams in an on-beam region obtained by turning on beams of a partial region of the beam array, while sequentially switching on-beam regions, a reflected charged particle signal from the mark is detected to calculate a position of the beam in each of the on-beam regions, and the shift amount distribution is obtained using the calculated positions of the beam in the on-beam regions.

4. The aperture correction amount calculation method for an aperture array substrate according to claim 1, wherein
a plurality of measurement positions are set within the beam array,
each of the plurality of measurement points is assigned a block region that is part of the beam array, and
an amount of current is measured for each of the plurality of measurement points to obtain the shift amount distribution.

5. The aperture correction amount calculation method for an aperture array substrate according to claim 1, wherein the representative value is an average value or a median value of the plurality of shift amounts within the block region.

6. An aperture array substrate including a plurality of apertures whose positions or dimensions are corrected based on a correction amount calculated using the aperture correction amount calculation method for an aperture array substrate according to claim 1.

7. A blanking aperture array substrate comprising: blankers that perform blanking control on each beam of the multiple charged-particle beams that pass through respective apertures; and control circuits that apply voltages to the blankers, wherein positions of a plurality of apertures are corrected based on a correction amount calculated using the aperture correction amount calculation method for an aperture array substrate according to claim 1, and the blankers and the control circuits are formed in accordance with the corrected positions of the respective apertures.

8. A multiple charged-particle beam writing apparatus comprising:
a beam source that emits a charged particle beam;
a shaping aperture array substrate, which is divided into regions serving as blocks and in which a plurality of first apertures with positional shifts or dimensional variations are formed on a block-by-block basis, a region that includes all the plurality of first apertures is irradiated with the charged particle beam, and multiple beams are formed by portions of the charged particle beam passing through the plurality of respective first apertures;
a blanking aperture array substrate, in which a plurality of second apertures are formed through which corresponding respective beams among the multiple beams pass, and each second aperture is provided with a blanker for performing blanking deflection on the beam; and
a deflector that deflects, in a collective manner, the beams that have passed through the plurality of second apertures and adjusts a beam irradiation position on a writing target substrate.

9. The multiple charged-particle beam writing apparatus according to claim 8, wherein the plurality of second apertures are divided into regions serving as blocks, and the positions of the second apertures are shifted on a block-by-block basis.

10. A multiple charged-particle beam writing method comprising:
emitting a charged particle beam;
irradiating, with the charged particle beam, a shaping aperture array substrate, which is divided into regions serving as blocks and in which a plurality of first apertures with positional shifts or dimensional variations are formed on a block-by-block basis, and forming multiple beams by portions of the charged particle beam passing through the plurality of respective first apertures;
performing on-off control on each beam using a blanking aperture array substrate, in which a plurality of second apertures are formed through which corresponding respective beams among the multiple beams pass, and each second aperture is provided with a blanker for performing blanking deflection on the beam; and
deflecting, in a collective manner, the beams that have passed through the plurality of second apertures using a deflector to radiate the beams onto a writing target substrate.

11. The multiple charged-particle beam writing method according to claim 10, wherein the plurality of second apertures are divided into regions serving as blocks, and positions of the plurality of second apertures are shifted on a block-by-block basis.
